(19) United States
(12) Patent Application Publication
(10) Pub. No.: US 2017/0343708 A1
(43) Pub. Date: Nov. 30, 2017

(54) MANUFACTURING METHOD FOR OPTICAL ELEMENT

(71) Applicant: NGK INSULATORS, LTD., Nagoya-City (JP)

(72) Inventors: Kousuke NIWA, Niwa-Gun (JP); Keiichiro ASAI, Nagoya-City (JP); Shoichiro YAMAGUCHI, lchinomiya-City (JP); Jungo KONDO, Miyoshi-Shi (JP)

(73) Assignee: NGK INSULATORS, LTD., Nagoya-City (JP)

(21) Appl. No.: 15/677,502

(22) Filed: Aug. 15, 2017

Related U.S. Application Data
(63) Continuation of application No. PCT/JP2016/054713, filed on Feb. 18, 2016.

(30) Foreign Application Priority Data
Feb. 20, 2015 (JP) 2015-031471
May 18, 2015 (JP) 2015-101102

(51) Int. Cl. G02B 5/18; B29C 33/42; G03F 7/00; H01S 5/00

(52) U.S. Cl. CPC G02B 5/1852; H01S 5/0078; B29C 33/424; G02B 5/1857; G03F 7/0002

(57) ABSTRACT

It is provided an assembly including an optical material layer composed of a metal oxide, an underlying layer provided over the optical material layer and composed of a metal or a metal silicide, and a resin layer provided over the underlying layer. A mold including a design pattern corresponding with the fine pattern to the resin layer of the assembly to transcript the design pattern to the resin layer. The resin layer and underlying layer are etched to form an opening in the resin layer and underlying layer to expose the optical material layer through the opening. The optical material layer is etched using the underlying layer as a mask to form the fine pattern in the optical material layer.

### TECHNICAL FIELD

The present invention relates to a method of producing an optical device, such as a grating device.

### BACKGROUND ARTS

The use of a nanoimprint method has been considered as a method for forming a diffraction grating included in a semiconductor laser element. The nanoimprint method is applied to the formation of the diffraction grating, which has an advantage because manufacturing costs of devices, such as a semiconductor laser, can be reduced, and the like.

In forming a diffraction grating by the nanoimprint method, first, a resin layer is formed on a semiconductor layer where the diffraction grating is to be created.

A mold having a concave-convex pattern corresponding to the shape of the diffraction grating is pressed onto the resin layer, and in this state, the resin layer is then hardened. In this way, the concave-convex pattern of the mold is imprinted into the resin layer. Thereafter, the shape of the resin layer is transferred to the semiconductor layer, thereby forming a fine structure in the semiconductor layer.

Patent Document 1 describes a method for manufacturing a distributed feedback semiconductor laser using the nanoimprint method. In this method, patterning of a semiconductor layer for forming a diffraction grating of the distributed feedback semiconductor laser is performed by the nanoimprint method.

Non-Patent Documents 1 and 2 describe fabrication of a sub-wavelength structured wide-band wavelength plate using the nanoimprint method.

Further, Non-Patent Document 3 describes how the nanoimprint technology is applied to fabricate optical devices. Such optical devices can include, for example, a wavelength selective element, a reflection control element, and a Moth-Eye structure.

For example, Patent document 3 discloses procedure for forming a diffraction grating by nanoimprinting method.

For example, when the diffraction grating is formed by nanoimprinting method, a resin layer is formed on a semiconductor layer in which the diffraction grating is to be formed. A mold having concave and convex pattern corresponding with the shape of the diffraction grating is then pressed onto the resin layer. In this state, the resin layer is exposed to irradiation of UV light having an optional wavelength or optional temperature condition so that the resin layer is cured. The concave and convex pattern of the mold is thereby transcripted onto the resin layer. Thereafter, a residual film of a resin is removed by dry ashing treatment and dry etching is performed so that the pattern of the resin layer is transcripted onto the semiconductor layer. A fine structure is thereby formed on the semiconductor layer.

In this case, as described above, after the Bragg grating pattern of the mold is transcripted onto the resin layer, it is necessary to remove the residual film of the resin by dry etching (ashing) treatment.

According to descriptions of Non-Patent document 4, it is necessary to remove the residual film of resin as one of various steps after the nanoimprinting process, according to prior nanoimprinting techniques. As a solution for reducing the number of process steps, nano electrode lithography technique is proposed (A conductive mold contacts a substrate at a part which is formed as an oxide pattern).

Further, according to description of patent document 4, it is necessary to remove the residual film after nanoimprinting according to prior procedure (0003 and FIG. 8). It is further described that its object is to provide a method of forming fine mask pattern in which the residual film is not present on the substrate or a thin pattern can be formed. Specifically, an inorganic material such as SOG or the like is embedded in a recess of a resin mold described in FIG. 1 or the like (spin coating and etch back, FIG. 1) and adsorbed onto the surface of the substrate. The resin mold is then released to form concaves and convexes whose precision is higher than that obtained by the nanoimprinting and removal of the residual film according to the prior arts.

[Patent Document 1] Japanese Patent Publication No. 2013-016650A

[Patent Document 2] Japanese Patent Publication No. 2009-111423A

[Patent Document 3] WO 2015/166852 A1

[Patent Document 4] Japanese Patent Publication No. 2011-066273A

[Non-Patent Document 1]

“Polymeric Wide-Band Wave Plate Produced via Nanoimprint Subwavelength Grating,” KONICA MINOLTA TECHNOLOGY REPORT, Vol. 2 (2005), pages 97 to 100

[Non-Patent Document 2]

“Challenge for production of highly-functional optical elements at low costs—Realization of sub-wavelength periodic structure by glass imprint method” Synthesiology, Vol. 1, No. 1 (2008), pages 24 to 30

[Non-Patent Document 3]

Furuta, “Nanoimprint technology and its application to optical devices” monthly magazine “Display” June 2007, pages 54 to 61

[Non-Patent Document 4]

“New fine pattern transcription technique” NTT technical Journal, 2008, 10, pages 17 to 20

### SUMMARY OF THE INVENTION

The inventors have tried to form an optical waveguide layer over a supporting body via a cladding layer with a concave-convex pattern having a pitch of several hundreds of nanometers (Bragg grating pattern) on the surface of the optical waveguide layer.

However, when it was tried to remove the resin residual film by ashing after the transcription of the fine pattern onto the resin layer and the residual resin mask is used to etch an optical material layer, the precision of the transcription of the fine pattern may be deteriorated. That is, for example, in the case that Bragg grating is formed on the optical material layer, the precision of the shape of the concaves may be deteriorated and it may be difficult to form the concave deeply.

An object of the present invention is to transcript a fine pattern of a mold onto a resin layer by imprint method and use the resin layer as a mask to form a fine pattern on an optical material layer, so that the precision of the shape of the optical material layer can be improved and a deeper concaves can be formed.

The present invention provides a method of producing an optical device comprising a fine pattern formed therein, said method comprising the steps of:

providing an assembly comprising an optical material layer comprising a metal oxide, an underlying layer provided over said optical material layer and comprising a metal or a metal silicide, and a resin layer provided over said underlying layer, and contacting a mold comprising a design pattern corresponding with said fine pattern to said resin layer of said assembly to transcript said design pattern onto said resin layer;

etching said resin layer and said underlying layer to form an opening in said resin layer and said underlying layer to expose said optical material layer through said opening; and

etching said optical material layer using said underlying layer as a mask to form said fine pattern in said optical material layer.

When the optical material layer is etched using the resin layer with the fine pattern of the mold transcripted as a mask, the precision of the shape of the recesses formed in the optical material layer may be low and the depth of the recesses is limited. The inventors studied the cause of the phenomenon. As a result, when the residual film of the unnecessary resin remained on the optical material layer is removed by ashing, it is considered that the thickness of the resin residual film may be deviated at locations, resulting in deviation of the etching process of the optical material layer.

In addition to this, as a high refractive index is required for an optical device such as an optical waveguide, a metal oxide forming the optical material layer is thus made of a material hard to process in many cases. As described above, the optical material layer is hard to process, so that the shape of the resin mask is susceptible to deterioration when the optical material layer is etched. There causes are combined so that it becomes difficult to form the deep convexes in the optical material layer by etching at a high precision.

Based on the above findings, the inventors reached the idea described below. That is, an underlying layer composed of a metal or a metal silicide is interposed between the optical material layer composed of a metal oxide and the resin layer to which the fine pattern of the mold is transcripted, the resin layer and underlying layer are etched to form openings, and the underlying layer is used as a mask to etch the optical material layer provided thereunder to transcript the fine pattern onto the optical material layer. It is thus possible to alleviate the necessity of the ashing for removing the resin residual film on the optical material layer, and to prevent the deterioration of the shape of the convexes of the hard-to process optical material layer due to the fine deviation of the thickness of the resin residual film and deterioration of the shape of the resin mask. It becomes thereby possible to form the deeper convexes.

Further, according to the method of the non-patent document 4, it is necessary to produce a new mold and to introduce devices such as electrodes and electric source. Further, according to the method of patent document 4, it is necessary to introduce steps of producing a resin mold, of embedding a material into the resin mold and of adsorbing it onto a base material.

### BRIEF DESCRIPTION OF DRAWINGS

FIG. 1(a) shows an assembly (or part) 20 composed of a supporting body 1, an optical material layer 2 and a resin layer 3, FIG. 1(b) shows the state that a design pattern A of a mold 5 is transcripted onto a resin layer 4, and FIG. 1(c) shows the state that a fine pattern B is transcripted onto the resin layer.

FIG. 2(a) shows the state that the optical material layer is etched using a resin mask 7, and FIG. 2(b) shows an optical material layer 6 with a fine pattern C formed thereon.

FIG. 3 is a photograph showing a Bragg grating formed according to a comparative example.

FIG. 4(a) shows an assembly 21 composed of the supporting body 1, the optical material layer 2, an underlying layer 11 and the resin layer 3, FIG. 4(b) shows the state that the design pattern A of the mold 5 is transcripted onto the resin layer, and FIG. 4(c) shows the resin layer 4 with the fine pattern B transcripted thereon.

FIG. 5(a) shows the state that a resin layer 13 and underlying layer 12 are patterned to form openings 13a and 12a, FIG. 5(b) shows the state that a fine pattern is formed on an optical material layer 15 using the underlying layer as a mask, and FIG. 5(c) shows the state that an underlying layer 16 is removed.

FIG. 6 is a photograph showing a Bragg grating formed in the inventive example.

### MODES FOR CARRYING OUT THE INVENTION

The present invention will be described in more detail below, with reference to the accompanying drawings as appropriate.

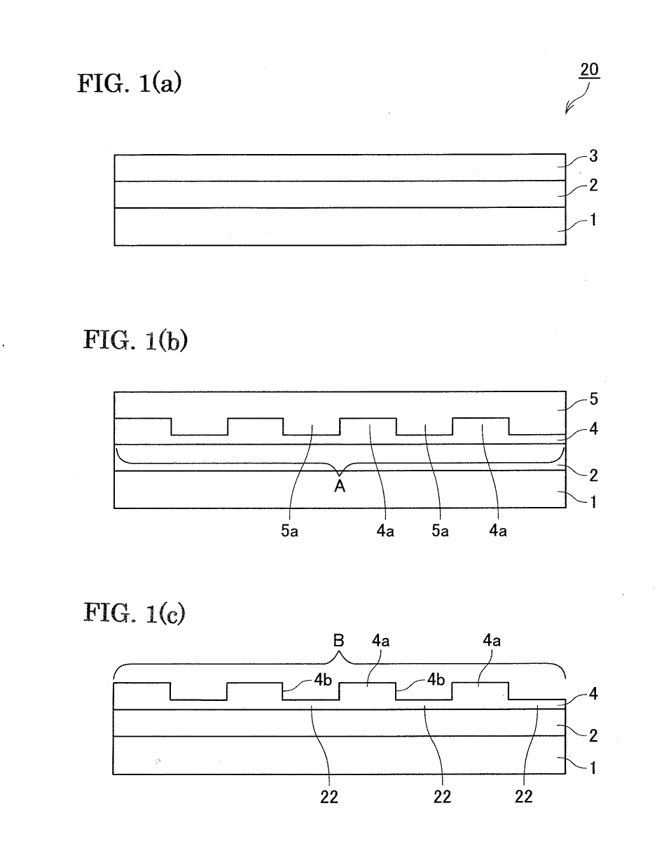

FIGS. 1 to 3 relate to an comparative example.

First, as shown in FIG. 1(a), an optical material layer 2 is formed on a supporting body 1, and a resin layer 3 is formed thereon to obtain an assembly 20.

Then, as shown in FIG. 1(b), a mold 5 is contacted with the resin layer 3 to transcript a design pattern A of the mold onto the resin layer. The design pattern A of the mold 5 is composed of many convexes 5a periodically formed, for example, and a resin 4a is filled into spaces between the adjacent convexes. Then, the mold 5 is removed to provide a resin layer 4 with a fine pattern B transcripted, as shown in FIG. 1(c). 4a represents convexes and 4b represents concaves between the convexes.

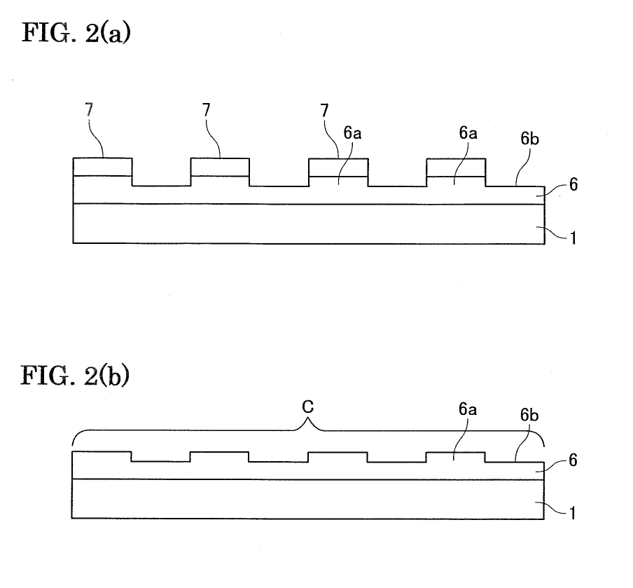

Here, as unnecessary resin is left under the concaves 4b as residual films 22, ashing is performed to remove the resin residual films 22. The optical material layer is thereby exposed to the concaves of the resin layer. Then, as shown in FIG. 2(a), a resin layer 7 is used as a mask to perform the etching of the optical material layer to form concaves 6b in the optical material layer. Then, the resin layer 7 is removed so that an optical material layer 6 is obtained with a fine pattern C transcripted thereon, as shown in FIG. 2(b). 6a represents convexes.

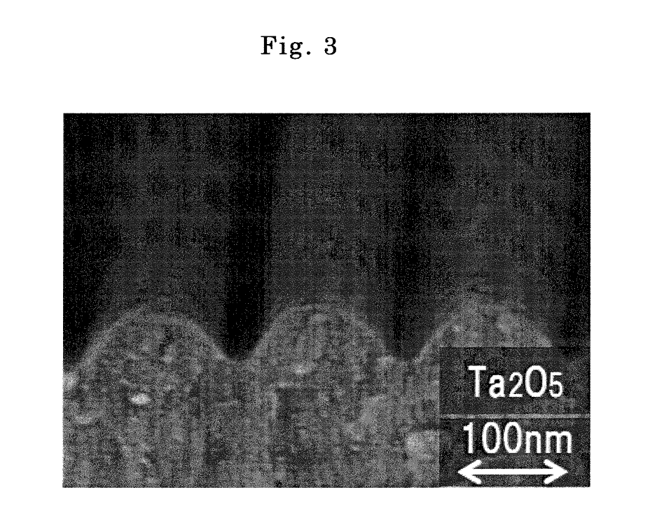

FIG. 3 shows the shape of a Bragg grating obtained according to the comparative example. The concave has a curved shape and its depth is limited.

Here, as the thickness of the resin residual film 22 is deviated depending on the locations, in the step of removing the unnecessary resin residual film remaining on the optical material layer by ashing, it is considered that times required for reaching the optical material layer is deviated to prevent the etching process at a high precision. Further, as it is difficult to process the optical material layer made of a metal oxide, corners of the resin mask 7 is etched at the same time so that the precision of shape of the resin mask is deteriorated. As such, the thickness of the resin residual film is deviated, the optical material layer 2 is hard to process, and the shape of the resin mask is deteriorated. It is thereby difficult to form deep concaves on the optical material layer by etching at a high precision.

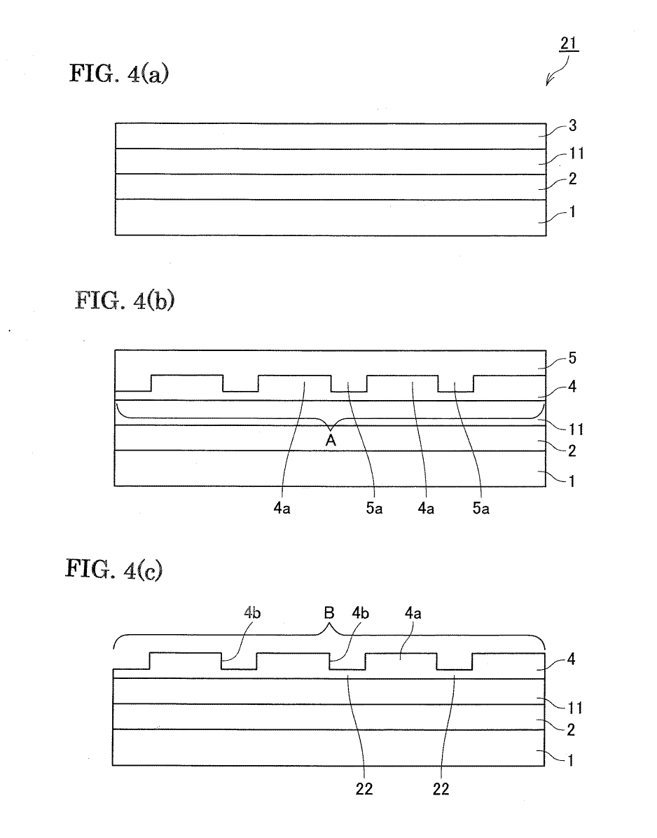

FIGS. 4 to 6 relates to am example according to the present invention.

First, as shown in FIG. 4(a), an optical material layer 2 is formed on a supporting body 1, an underlying layer 11 is formed thereon and a resin layer 3 is formed thereon to obtain an assembly 21.

Then, as shown in FIG. 4(b), a mold 5 is contacted with the resin layer to transcript a design pattern A of the mold onto the resin layer. The design pattern A of the mold is composed of periodically formed many convexes 5a and a resin is filled between the adjacent convexes, for example.

The mold is then removed to obtain a resin layer 4 onto which a fine pattern B is transcripted, as shown in FIG. 4(c). 4a represents convexes and 4b represents concaves between the convexes.

Here, although unnecessary resin is left as a residual film 22 under the concaves 4b, the ashing for removing the residual resin film is not performed, according to the present example.

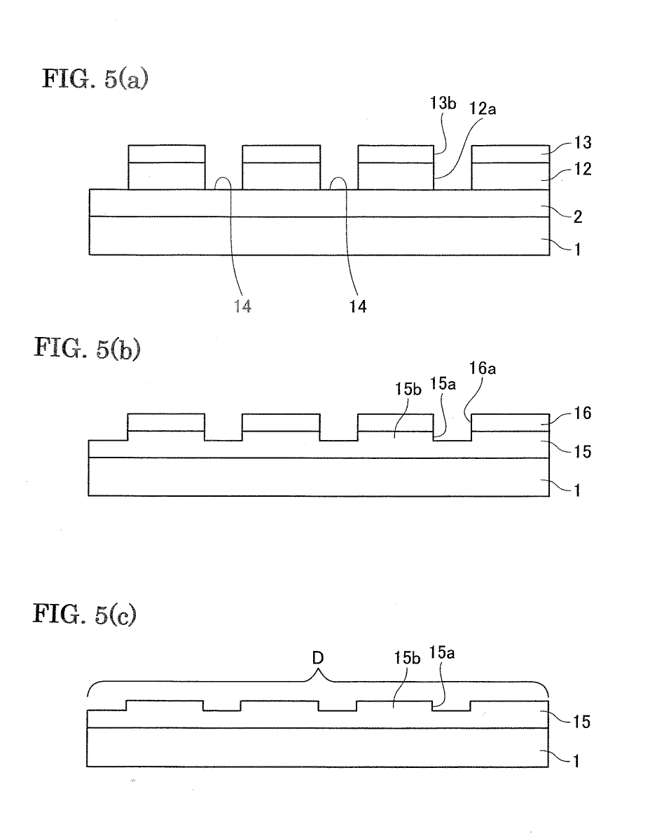

That is, the resin layer 4 and underlying layer 11 are etched at this stage. By the etching, the whole of the resin layer 4 is removed, the underlying layer 11 is exposed in the concaves 4b with the residual film 22 at first, and then the etching of the underlying layer 11 is initiated. As a result, as shown in FIG. 5(a), openings 13b are formed in a resin layer 13, and the underlying layer 12 is etched under the openings 13b to form openings 12a. A surface 14 of the optical material layer 2 is exposed through the openings 13b and 12a.

At this stage, the resin residual film is removed, and at the same time, the removal of the underlying layer provided under the residual film is proceeded, so that the etching of the underlying layer becomes a main step. As a result, in the case that the thickness of the resin residual film is deviated, the influence of the deviation is reduced during the step of proceeding the etching of the underlying layer. Further, as it is easier to etch the underlying layer made of a metal or a metal silicide than a metal oxide, it is possible to prevent the deterioration of the shape of the resin mask 13 during the process of the etching of the underlying layer.

Then, as shown in FIG. 5(b), the optical material layer is etched to form convexes 15b and concaves 15a of a predetermined pattern. After the etching on this stage, the resin layer 13 is removed and the underlying layer 12 functioning as a mask is also thinned so that an underlying layer 16 is left. Openings 16a are formed in the underlying layer 16, and concaves 15a are exposed through the openings 16a.

Then, the residual underlying layer 16 is removed to expose the optical material layer 15 as shown in FIG. 5(c). A fine pattern D is formed in the optical material layer 15, and the fine pattern D is composed of convexes 15b and concaves 15a periodically formed.

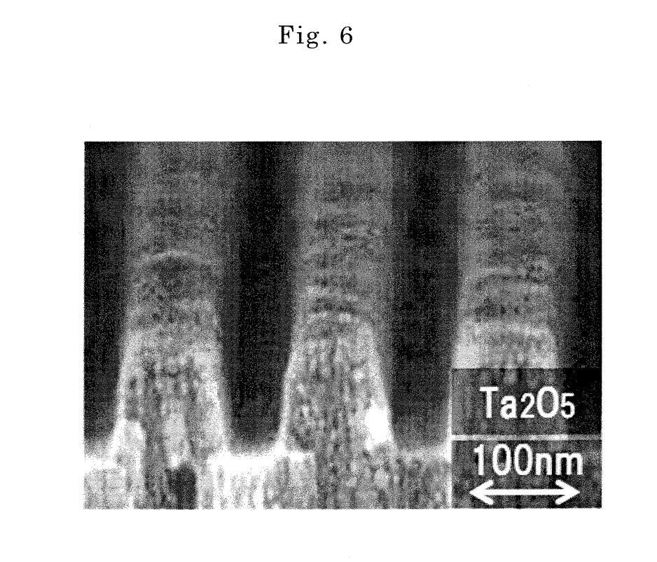

According to the present invention, the underlying layer 12 is used as a mask to etch the metal oxide. In this case, it becomes possible to apply etching conditions and etchant which can prevent the etching of the metal or the metal silicide and facilitate the etching of a metal oxide. It is thus possible to form deeper concaves at a higher precision, for example as shown in FIG. 6.

As the advantageous effects of the present invention, for example as to the shape of the concave, it was possible to obtain a structure in which a distance between pitches is contained in a range of “a speculated distance between pitches ±0.5 nm (an average per one pitch), a depth of the metal oxide after the etching is contained in a range of” a depth of 100 nm or larger ±5 nm” and a taper angle of the concaves is 70 degrees or larger. Further, as described above, it becomes possible to perform the etching process without the conventional process (removal of the resin residual film by ashing after nanoimprinting).

The elements of the present invention will be described below.

When imprinting a design pattern of a mold and a resin layer 3 is composed of a thermoplastic resin, the resin layer 3 is softened by being heated up at a softening point of the resin or higher and the mold is pressed against the resin layer, allowing the resin to be deformed. After being cooled down, the resin layer 3 is cured.

When the resin layer 3 is made of a thermosetting resin, the mold is pressed against the uncured resin layer, causing the resin to be deformed. Subsequently, the resin layer is heated up at a polymerization temperature of the resin or higher, and thereby can be cured. When the resin layer 3 is formed of a photo curable resin, the mold is pressed against the uncured resin layer, thereby deforming the resin to transfer the designed pattern to the resin layer. Then, the resin layer 3 is irradiated with light and thereby can be cured.

Specific materials for the supporting body are not particularly limited, but includes, for example, lithium niobate, lithium tantalate, AlN, SiC, ZnO, glass, such as silica glass, synthetic silica, quartz crystal, and Si. Here, preferable materials for the supporting body are a glass such as silica glass, synthetic silica, quartz crystal, and Si in terms of the easiness of processing the supporting body.

The thickness of the supporting body is preferably 250 μm or more in terms of handling, and preferably 1 mm or less in terms of downsizing.

The metal oxide forming the optical material layer includes silicon oxide, zinc oxide, tantalum oxide, lithium niobate, lithium tantalate, titanium oxide, aluminum oxide, niobium pentoxide, and magnesium oxide. A refractive index of the optical material layer is preferably 1.7 or more and further preferably 2 or more.

To further improve the optical damage resistance of the optical waveguide, the optical material layer may contain one or more kinds of metal elements selected from the group consisting of magnesium (Mg), zinc (Zn), scandium (Sc), and indium (In). In this case, magnesium is particularly preferable. Crystals of the optical material layer can contain a rare-earth element as a doping agent. Suitable rare-earth elements include, particularly preferably, Nd, Er, Tm, Ho, Dy, and Pr.

The thickness of the optical material layer is not particularly limited. In terms of reducing the propagation loss of light, the thickness of the optical material layer is preferably in a range of 0.5 to 3 μm.

In the case that it is provide a lower clad layer or upper clad layer contacting the optical material layer, the thickness of each clad layer is made preferably larger so that the leakage of the propagating light into the supporting body can be reduced. On the viewpoint, the thickness of each clad layer may preferably be made 0.5 μm or larger.

In the case that the lower and upper clad layers are provided, they are formed of a material whose refractive indices are lower than that of the material of the optical material layer, and may be formed of silicon oxide, tantalum oxide or zinc oxide. Further, by doping the lower clad layer and upper clad layer, the refractive indices can be adjusted. Such dopant includes P, B, Al and Ga.

The material of the underlying layer provided under the resin layer is a metal or a metal silicide.

The metal forming the underlying layer includes Ti, Cr, Mo, W, Ta, Si, Ni, Al, V, Fe, Nb, Re, Co, Pd, Pt or the alloys thereof.

Further, the metal silicide forming the underlying layer includes tungsten silicide, vanadium silicide, iron silicide, niobium silicide, molybdenum silicide, rhenium silicide, chromium silicide, cobalt silicide, nickel silicide, palladium silicide and platinum silicide.

More preferably, the metal forming the underlying layer is Ti, Cr, Ni, Al or the alloys thereof.

The optical material layer, lower clad layer, upper clad layer and underlying layer may be a single layer, or alternatively a multi-layer film.

Further, the optical material layer, lower clad layer, upper clad layer and underlying layer may be formed by a thin-film formation method. Suitable thin-film formation methods can include sputtering, vapor deposition, and CVD.

The fine pattern formed in the supporting body or the optical material layer means a pattern with a pitch of 10 μm or less. The pattern having a pitch of 1 μm or less is particularly effective. Specific components with such a fine pattern can include, for example, a sub-wavelength structure wide-band wavelength plate, a wavelength selective element, a reflection control element, a Moth-Eye structure, a Bragg grating, and a ridge optical waveguide.

As shown in FIG. 5(a), when the underlying layer is etched, the following etching method is preferred.

That is, in selecting a gas species in performing dry etching, it is preferred that a selection ratio of an etching rate of the resin and that of the metal or metal silicide is large and that the gas species does not etch the metal oxide layer. As the dry etching method using the gas species, it is listed ICP (induction coupling plasma) dry etching. As the gas species, a chlorine based gas such as BCl₃ or Cl₂ is listed as an example, and a fluorine based gas may be used.

According to the present invention, when the resin layer and underlying layer are etched, both layers can be etched in a single etching step. By this, the treatment of the residual film (ashing) of the resin film only becomes unnecessary. Here, the single etching step means a step that the assembly is contacted with the echant to perform the etching until the contact of the assembly to the etchant is terminated. During the etching step, the gas species is preferably of a single kind, although the kind and composition of the gas species may be changed.

Further, as shown in FIG. 5(b), in the case that the underlying layer is used as a mask to etch the metal oxide layer, the etching method is preferably as follows.

That is, when the dry etching is performed, the gas species may preferably be selected so that the selection ratio of the etching rate of the metal or metal silicide and the etching rate of the metal oxide is large. Further, as the dry etching technique using the gas species, ICP dry etching is exemplified as such technique. As an example, a fluorine-based gas such as CHF₃, C₂F₆ or the like may be listed as a candidate, although it is not limited to them.

### EXAMPLES

(Specification of Mold)

The following sample was prepared as a mold. Specifically, a grating mold was prepared by using ArF immersion stepper exposure. The grating had a pitch of 200 nm, a depth of 100 nm and duty ratio of 1:1. Further, the dimensions of the transcripted region was made 200 μm in length and 200 μm in width. The pitch of the grating was measured and proved to be 200±0.5 nm or smaller as desired.

As to this mold, “HD-1101Z” (produced by DAIKIN Co. Ltd.) was used to form a mold release layer on the surface of the mold.

### Example 1

An optical device was produced according the method described referring to FIGS. 4 and 5.

Specifically, on a supporting body 1 made of Si and of φ of 6 inches, a lower clad layer made of SiO₂ was formed as a film in 1.0 μm, and an optical material layer 2 of Ta₂O₅ was formed on the surface in 1.0 μm. Further, an underlying layer 11 (thickness of 50 nm) made of Ti was formed on the upper surface by sputtering, and a nanoimprint resin layer 3 was applied to obtain an assembly 21. Then, the mold 5 was pressed, the curing was performed by ultraviolet light, and the mold was released, so that the grating mask pattern B was formed on the resin layer (FIG. 4(c)).

Then, by dry etching using a chlorine based gas (BCl₃) and the resin mask pattern as a mask, the underlying layer 11 was etched to the surface of the optical material layer, and the residual film of the resin was removed at the same time (FIG. 5(a)). Further, the underlying layer 12 was used as a mask and the optical material layer was subjected to dry etching by a fluorine based gas (CHF₃), so that the etching was continued until a depth of 100 nm. The residue of the underlying layer was then removed.

As described above, it was formed a Bragg grating having a pitch of 200 nm, a depth of 100 nm and a duty ratio of 1:1. The grating part had the shape that it was extended downwardly with respect to the surface of Ta₂O₅ as a standard level.

The pitch was measured in the transcripted region of 200 μm in length and 200 μm in width using an AFM capable of high precision measurement of ±0.04 nm or smaller and a measuring system using diffraction ray of laser light. As a result, over the whole of the wafer plane of φ 6 inches, it can be obtained a desired pitch of ultra-high precision of 200±0.2 nm, ever when it was measured the grating of a small transcripted region (small pattern density).

FIG. 6 shows an SEM photograph of the thus obtained Bragg grating (magnification of 100, 000 fold). It was proved that a deep convexes were formed and the shape of each convex was near a rectangular shape.

### Comparative Example 1

An optical device was produced according the method described referring to FIGS. 1 and 2.

Specifically, on a supporting body 1 made of Si and of φ of 6 inches, a lower clad layer made of SiO₂ was formed as a film in 1.0 μm, and an optical material layer 2 (1.0 μm) of Ta₂O₅ was formed on the surface by sputtering. A nanoimprinting resin layer 3 was applied to obtain an assembly 20 (FIG. 1(a)). Then, the mold was pressed, the curing was performed by ultraviolet light, and the mold was released, so that the grating mask pattern B was formed on the resin layer 4 (FIG. 1(c)). The resin residual film 22 was removed by plasma ashing.

Then, by using the resin layer 7 as a mask, the optical material layer 2 was subjected to dry etching using a fluorine based gas (CHF₃) (FIG. 2(a)).

As described above, it could not be produced a Bragg grating (pitch of 200 nm, depth of 100 nm and duty ratio of 1:1) having a small pattern density in which the transcripted regions of 200 μm in length and 200 nm in width were dispersed.

That is, FIG. 3 shows an SEM of the thus obtained Bragg grating (magnification of 100,000). It was proved that the depth of the convex was as small as about 50 nm and the profile of the convex was roundly curved.

As described above, according to the present invention, it becomes possible to obtain a diffraction grating with convexes and concaves formed therein at a precision of shape comparable with that of the convexes and concaves formed in the resin direct after the nanoimprinting, without performing the step of removing the residual film required in prior nanoimprinting process.

### Example 2

In the Example 1, the material of the underlying layer was changed to chromium. As a result, it was produced a Bragg grating whose shape was substantially same as that obtained in the Example 1.

### Example 3

In the Example 1, the material of the underlying layer was changed to nickel. As a result, it was produced a Bragg grating whose shape was substantially same as that obtained in the Example 1.

### Example 4

In the Example 1, the material of the underlying layer was changed to aluminum. As a result, it was produced a Bragg grating whose shape was substantially same as that obtained in the Example 1.

### Example 5

In the Example 1, the material of the underlying layer was changed to tungsten silicide (WSix). As a result, it was produced a Bragg grating whose shape was substantially same as that obtained in the Example 1. The grating part had the shape that the grating was formed under the surface of Ta₂O₅ as a standard level.

Further, in the measurement of the pitch in the transcripted region of 200 μm in length and 200 μm in width, it was obtained the desired pitch comparable with that obtained in the Example 1.

1. A method of producing an optical device comprising a fine pattern, said method comprising the steps of:
providing an assembly comprising an optical material layer comprising a metal oxide, an underlying layer provided over said optical material layer and comprising a metal or a metal silicide, and a resin layer provided over said underlying layer, and contacting a mold comprising a design pattern corresponding with said fine pattern to said resin layer of said assembly to transcript said design pattern to said resin layer;
etching said resin layer and said underlying layer to form an opening in said resin layer and said underlying layer to expose said optical material layer through said opening; and
etching said optical material layer using said underlying layer as a mask to form said fine pattern in said optical material layer.

2. The method of claim 1, wherein said resin layer is etched without performing a treatment of a residual film.

3. The method of claim 1, wherein said resin layer and said underlying layer are etched using a single kind of a gas species.

4. The method of claim 1, wherein said resin layer comprises an ultra-violet light curable resin, a thermosetting resin or an electron beam curable resin.

5. The method of claim 1, wherein said assembly comprises a supporting body supporting said optical material layer.

6. The method of claim 1, wherein said fine pattern comprises a sub-wavelength structure, a wide-band wavelength plate, a wavelength selective element, a reflection control element, a Moth-Eye structure or a Bragg grating.

7. The method of claim 1, wherein said underlying layer comprises said metal.

8. The method of claim 1, wherein said underlying layer comprises said metal silicide.

9. The method of claim 8, wherein said underlying layer comprises tungsten silicide.
